(19) United States
(12) Patent Application Publication
(10) Pub. No.: US 2013/0176046 A1
(43) Pub. Date: Jul. 11, 2013

(54) MOBILE TRANSFORMER TESTING SYSTEM

(71) Applicants: Johnathan Christopher Brown, Marietta, GA (US); John Michael Engstrom, Chicago, IL (US); David Warren Deines, Bradenton, FL (US); Chetan Raghu Aswathanarayana Polavaram, Mableton, GA (US); Christopher Michael Roche, Anaheim, CA (US); Fred Faro Noto, Stoney Creek (CA); Terry Joseph Geringer, Bradenton, FL (US)

(72) Inventors: Johnathan Christopher Brown, Marietta, GA (US); John Michael Engstrom, Chicago, IL (US); David Warren Deines, Bradenton, FL (US); Chetan Raghu Aswathanarayana Polavaram, Mableton, GA (US); Christopher Michael Roche, Anaheim, CA (US); Fred Faro Noto, Stoney Creek (CA); Terry Joseph Geringer, Bradenton, FL (US)

(73) Assignee: General Electric Company, Schenectady, NY (US)

(21) Appl. No.: 13/344,495

(22) Filed: Jan. 5, 2012

(51) Int. Cl. G01R 31/20

(52) U.S. Cl. 324/750.25

(57) ABSTRACT

A system includes a transformer testing system that includes a mobile platform configured to couple to a vehicle and an impulse testing system coupled to the mobile platform. The impulse testing system includes an impulse generator tower disposed in a lowered position along the mobile platform during transport by the vehicle. The transformer testing system also includes a lift system coupled to the mobile platform. The lift system is configured to lift the impulse generator tower from the lowered position to a raised position. The impulse testing system is configured to perform an impulse test of a high voltage power transformer while the impulse generator tower is disposed in the raised position. The transformer testing system also includes a protective cover disposed on the mobile platform. The protective cover is configured to surround a region having the impulse testing system.

### BACKGROUND OF THE INVENTION

The disclosed subject matter relates to large power distribution transformers, such as transformers disposed at a power plant that generates and distributes electricity to a power grid. More specifically, the disclosed subject matter relates to testing of these large power distribution transformers.

Transformers are devices that transfer electrical energy from one circuit to another through inductively coupled conductors, namely coils of the transformer. Transformers may be used to step up or increase, or step down or decrease, the voltage of an alternating current. In certain transformers, the coil consists of windings of wire wound around a ferromagnetic core. During use, transformers may be subject to maintenance issues, such as coronas, electrical breakdowns, internal arcing, insulation failure, and so forth. Thus, transformers may undergo regular testing to help determine the status and/or integrity of the transformer. For example, impulse testing may be used to determine the condition of insulation used in the transformer. Such impulse testing may be performed at a transformer repair shop remote from the facility where the transformer is installed. Thus, the entire transformer may be transported to the repair shop for the impulse testing. Unfortunately, the transportation of large, high voltage power transformers may be expensive. For example, the transformers may weigh thousands of kilograms, and may be tens and hundreds of cubic meters in size. Thus, the transportation may require use of large semi-trailer trucks and/or railway carriers. In addition, the repair shop may be far from the transformer facility, thereby increasing the duration of the maintenance outage associated with the impulse testing of the transformer.

### BRIEF DESCRIPTION OF THE INVENTION

Certain embodiments commensurate in scope with the originally claimed invention are summarized below. These embodiments are not intended to limit the scope of the claimed invention, but rather these embodiments are intended only to provide a brief summary of possible forms of the invention. Indeed, the invention may encompass a variety of forms that may be similar to or different from the embodiments set forth below.

In a first embodiment, a system includes a transformer testing system. The transformer testing system includes a mobile platform configured to couple to a vehicle and an impulse testing system coupled to the mobile platform. The impulse testing system includes an impulse generator tower disposed in a lowered position along the mobile platform during transport by the vehicle. The transformer testing system also includes a lift system coupled to the mobile platform. The lift system is configured to lift the impulse generator tower from the lowered position to a raised position. The impulse testing system is configured to perform an impulse test of a high voltage power transformer while the impulse generator tower is disposed in the raised position. The transformer testing system also includes a protective cover disposed on the mobile platform. The protective cover is configured to surround a region having the impulse testing system.

In a second embodiment, a system includes a transformer testing system. The transformer testing system includes a mobile platform configured to couple to a vehicle, an impulse testing system comprising an impulse generator tower having a rotatable base coupled to the mobile platform, and a lift system coupled to the mobile platform. The lift system is configured to move the impulse generator tower between a lowered transport position and a raised testing position. The transformer testing system also includes a cushioning system configured to cushion the impulse generator tower relative to the mobile platform in the lowered position during transport by the vehicle.

In a third embodiment, a system includes a transformer testing system. The transformer testing system includes a mobile platform configured to couple to a vehicle and an impulse testing system comprising an impulse generator tower having a rotatable base coupled to the mobile platform. The impulse generator tower comprises a plurality of tower segments configured to selectively connect and disconnect from one another. The transformer testing system also includes a lift system coupled to the mobile platform. The lift system is configured to move the impulse generator tower between a lowered transport position and a raised testing position. The plurality of tower segments are selectively disconnected from one another in the lowered transport position during transport by the vehicle. The plurality of tower segments are selectively connected together prior to lifting by the lift system.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a perspective view of an embodiment of a high voltage power transformer;

FIG. 2 is schematic diagram of an embodiment of a mobile transformer testing system;

FIG. 3 is a perspective view of an embodiment of a mobile transformer testing system with an impulse generator tower in a lowered position;

FIG. 4 is a perspective view of an embodiment of a mobile transformer testing system with an impulse generator tower in a raised position;

FIG. 5 is a side view of an embodiment of a lift system of a mobile transformer testing system;

FIG. 6 is a side view of an embodiment of a cushioning system for a mobile transformer testing system; and

FIG. 7 is a side view of an embodiment of a cushioning system coupled to a mobile transformer testing system.

### DETAILED DESCRIPTION OF THE INVENTION

One or more specific embodiments of the present invention will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present invention, the articles “a,” “an,” “the,” and “said” are intended to mean that there are one or more of the elements. The terms “comprising,” “including,” and “having” are intended to be inclusive and mean that there may be additional elements other than the listed elements.

As discussed in detail below, the disclosed embodiments provide systems for testing transformers, such as high voltage power transformers, using a mobile transformer testing system. High voltage power transformers may be used in the power distribution industry for stepping up or stepping down high voltage alternating currents (e.g., between approximately 35,000 to 500,000 volts). Again, the transformers may be used at power plants that generate and distribute electricity, e.g., tens, hundreds, or thousands of megawatts of electricity. Thus, the transformers are large and heavy, e.g., thousands of kilograms, and tens and hundreds of cubic meters in size. The insulation of such transformers may break down, or fail, during use, which may cause unscheduled maintenance outages. During a scheduled maintenance outage, the transformer may be tested to determine the condition of the insulation of the transformer, for example. In certain embodiments, the mobile transformer testing system is brought to the facility (e.g., power plant) where the transformer is installed. Next, the transformer testing system is prepared for testing. Once the transformer testing system is ready, the transformer is taken out of service and connected to the transformer testing system. The transformer testing system may be used to perform various tests, such as an impulse test, of the connected transformer to determine the condition of the transformer, such as the condition of the insulation. If the test results indicate the transformer is in satisfactory condition, the transformer is disconnected from the transformer testing system and placed back into service. Otherwise, the transformer may undergo any needed maintenance and/or repairs. After testing is complete, the mobile transformer testing system may be prepared for transport and sent to another facility for further testing of other transformers. Using the mobile transformer testing system to test the transformer at the facility where the transformer is installed may offer several advantages compared to shipping the transformer to a remote transformer repair shop for testing. For example, the transportation costs associated with shipping the high voltage power transformer to the repair shop may be avoided by using the transformer testing system. Such shipping costs may be high because of the size and weight of high voltage power transformers. In addition, on-site testing of the transformer may reduce the possibility of damage to the transformer associated with transport. Further, the repair shop may be located far from the facility where the transformer is located, which may increase the time associated with transporting the transformer. Thus, the duration and costs of the scheduled maintenance outage may be reduced by using the transformer testing system to test the transformer at the facility.

In certain embodiments, the mobile transformer testing system may include a mobile platform, an impulse testing system, a lift system, and a protective cover. The mobile platform may be coupled to a vehicle, which may be used to transport the transformer testing system from one facility to another. For example, the vehicle may be a motorized vehicle, such as a flatbed truck, or a trailer. The impulse testing system may be placed on the mobile platform and may include an impulse generator tower disposed in a lowered position along the mobile platform during transport by the vehicle. The lift system may also be coupled to the mobile platform and used to lift the impulse generator tower from the lowered position to a raised position. The impulse testing system may be used to perform an impulse test of the high voltage power transformer while the impulse generator tower is disposed in the raised position. The protective cover may be disposed on the mobile platform and used to surround a region having the impulse testing system. Thus, the protective cover may be used to protect the impulse testing system during transport. The protective cover may be removed from the impulse testing system during the impulse test. In certain embodiments, the transformer testing system may include a cushioning system that cushions the impulse generator tower relative to the mobile platform in the lowered position during transport by the vehicle. Thus, the cushioning system helps to protect the impulse generator tower from shock or vibration that it may experience during transport by the vehicle. In further embodiments, the impulse generator tower includes a plurality of tower segments configured to selectively connect and disconnect from one another. For example, the tower segments may be disconnected from one another during transport. Transport of the impulse generator tower in a disconnected configuration may help to prevent damage to the tower during transport. Upon arrival at the transformer facility, the tower segments may be connected to one another to prepare for testing of the transformer.

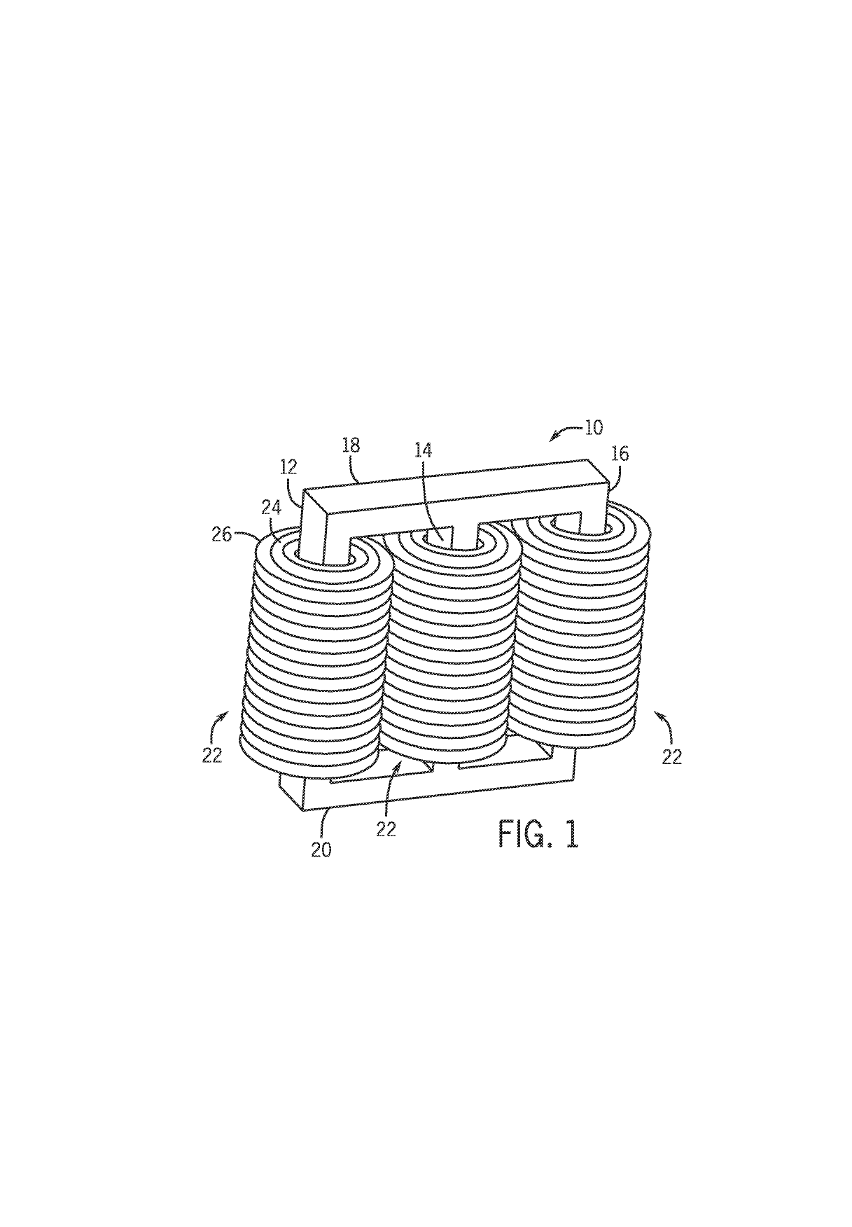

Turning to the drawings, FIG. 1 is a perspective view of a high voltage power transformer 10. Specifically, the high voltage power transformer 10 depicted in FIG. 1 may be a three phase distribution transformer. Thus, the core of the transformer 10 may include a first winding leg 12, a second winding leg 14, and a third winding leg 16. The transformer 10 also includes an upper yoke 18 and a lower yoke 20. In certain embodiments, the winding legs 12, 14, and 16, and the upper and lower yokes 18 and 20 may include a plurality of laminations formed from a magnetic material, such as, but not limited to, silicone steel, amorphous alloy, and so forth. A cylindrical phase winding 22 is positioned on each of the winding legs 12, 14, and 16. Each phase winding 22 includes a low voltage primary winding 24 and a concentric, high voltage secondary winding 26 located radially outward of the primary winding 24. The primary and secondary windings 24 and 26 are each formed by multiple layers, or coils, of conductive cabling connected in series. Each layer is formed by a plurality of turns of the conductive cabling connected in series.

The conductive cabling used to form the phase windings 22 may be non-insulated cabling. The use of non-insulated cabling necessitates the placement of an electrically-insulative material within the phase windings 22. More particularly, a solid, electrically-insulative material such as epoxy resin may be placed between adjacent turns, and between adjacent layers within the phase winding 22. The phase windings of oil-filled transformers are further insulated by oil (e.g., mineral oil) that surrounds the phase windings within such transformers. The placement of insulation between the adjacent turns and layers of the phase winding 22 is configured to prevent short-circuiting that would otherwise occur due to the differing electric potential between the adjacent layers and turns. The insulation is also configured to prevent short circuiting between adjacent phase windings 22, and between the phase windings 22 and adjacent conductive components. The solid insulative material is placed individually over each cable layer, and between adjacent turns in the particular layer, immediately after the layer has been wound. Hence, installation of the solid insulative material is integrated into the winding process for each phase winding 22. The condition of the insulation may be determined by impulse testing, for example, as described in detail below.

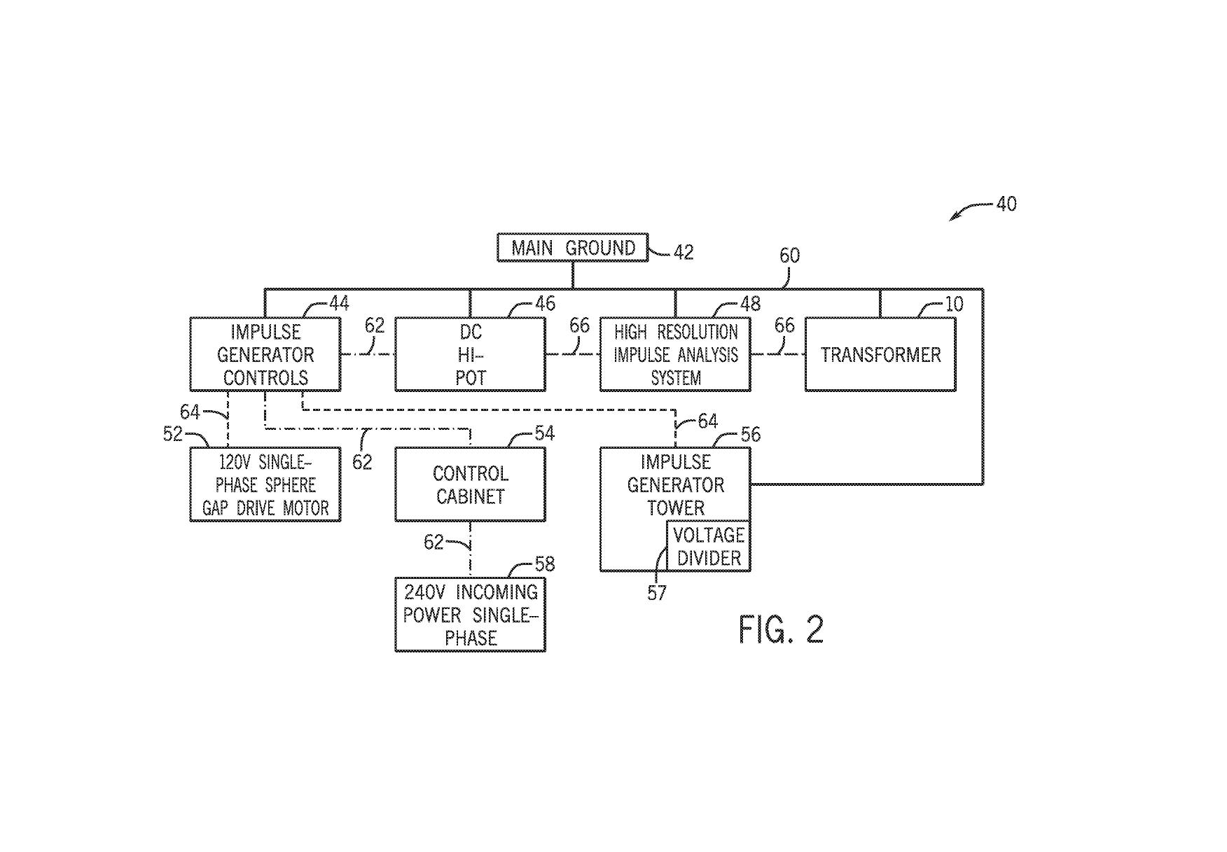

FIG. 2 is a schematic diagram of a mobile transformer testing system 40 that may be used to perform impulse testing of the transformer 10 according to various international standards, such as, but not limited to, IEC 60060-1 and IEC 60060-2. Although one arrangement of components of the transformer testing system 40 is shown in FIG. 2, other arrangements and configurations are possible as well. Specifically, the transformer testing system 40 may include a main ground 42 that provides a ground path for the various components of the transformer testing system 40. The main ground 42 may be physically connected to the earth or another ground to provide a return path for electric current. Next, the transformer testing system 40 may include impulse generator controls 44, or a control unit, configured to control the transformer testing system 40. Specifically, the impulse generator controls 44 may include a controller to operate the transformer testing system 40 and an operator interface to enable an operator to interact with the controller. A direct current (DC) high potential (hi-pot) testing device 46, or charging unit, may provide a high potential direct current during the impulse testing of the transformer 10. A high resolution impulse analysis system (HIAS) 48 may be used to analyze results of the impulse testing of the transformer 10. The transformer testing system 40 may also include a single phase sphere gap drive motor 52, which may be used at a voltage of approximately 120 volts. The sphere gap drive motor 52 may be used to adjust a gap between two spheres used to calibrate voltages of the transformer testing system 40. For example, the sphere gap drive motor 52 may be used to help prevent overvoltage of the transformer 10. A control cabinet 54 may be used as an interface between incoming power to the transformer testing system 40 and the impulse generator controls 44.

An impulse generator tower 56 is used to store an electrical potential during the impulse testing of the transformer 10. For example, the impulse generator tower 56 may be configured as a Marx generator to generate a high voltage pulse. Marx generators, or impulse generators, may be used to simulate the effects of lightning on power line gear and include a number of capacitors charged in parallel and connected in series by spark gap switches. Thus, the impulse generator tower 56 may include a plurality of impulse capacitors connected in series by spark gaps. In certain embodiments, the capacitors may be rated for greater than approximately 2 microfarads. The impulse capacitors may be charged with DC voltages up to, for example, 100 kV in order to generate the high voltage pulses. In certain embodiments, the impulse generator tower 56 may have a cumulative charging voltage greater than approximately 2000 kV. In addition, the impulse generator tower 56 may include front resistors and tail resistors to adjust the front time and time to half value of the test impulse. The front time is the amount of time for the voltage to rise from approximately zero volts to the required peak (or crest) voltage. The time to half value, or tail time, is the amount of time for the voltage to decay from the peak voltage to half of the peak voltage. The front time and tail time may be adjusted by varying the resistance of the front and tail resistors, respectively. In further embodiments, an impulse voltage divider 57 may be used to convert impulse voltages generated by the impulse generator tower 56 to a lower voltage level. The components of the impulse generator tower 56 may be supported by a plurality of insulating columns, or support columns, which may be made from a non-conductive material, such as glass fiber reinforced plastic. The switching spark gaps may be housed in a separate insulating column with slight air over pressure to help provide safe triggering. The insulating columns may be placed on a support base for support of the impulse generator tower 56. In certain embodiments, the support base may be made from steel. The transformer testing system 40 may also include a source of incoming power 58, which may be 240 volt single phase power, for example.

The main ground 42 may be connected to the impulse generator controls 44, the DC hi-pot 46, the HIAS 48, the transformer 10, and the impulse generator tower 56 via one or more ground cables 60. The ground cables 60 may be isolated from one another, isolated from any metal surface, and grounded at single points. The incoming power 58 may be provided to the control cabinet 54, the impulse generator controls 44, and the DC hi-pot 46 via one or more control power cables 62. Output signals from the impulse generator controls 44 may be transmitted to the single phase sphere gap drive motor 52 and the impulse generator tower 56 along one or more output cables 64. The HIAS 48 may be connected to the DC hi-pot 46 and the transformer 10 via one or more measurement cables 66. The measurement cables may be coaxial cables and be configured to enable the cables to be moved for connection to the transformer 10.

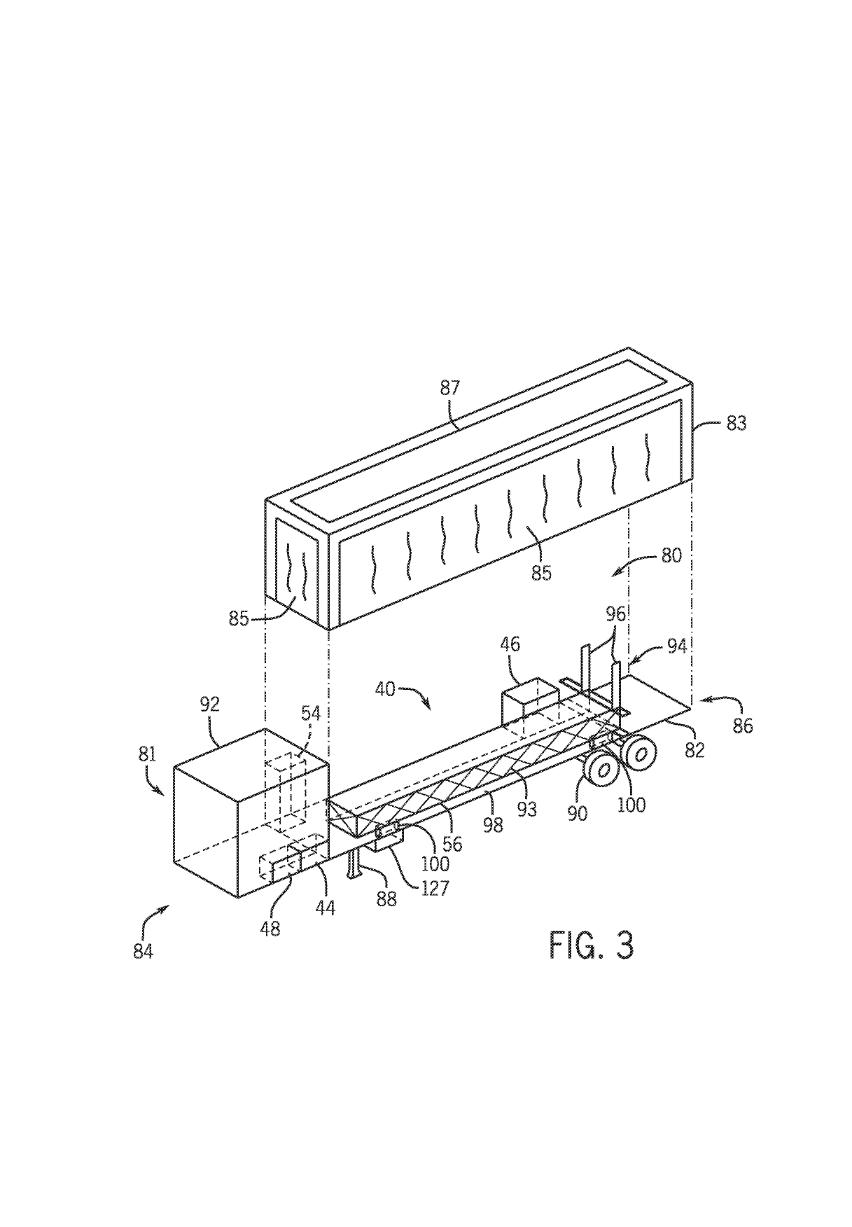

FIG. 3 is a perspective view of the mobile transformer testing system 40 in a lowered position 80 on a vehicle 81. The various components of the transformer testing system 40 are disposed on a mobile platform 82 of the vehicle 81. The vehicle 81 is illustrated as a trailer, which may be coupled to and transported by a motorized vehicle. In other embodiments, the vehicle 81 may be a motorized vehicle, such as a flatbed truck, having the mobile platform 82. In one embodiment, the mobile platform 82 may be obtained from Utility Trailer Manufacturing Company of City of Industry, Calif.. The mobile platform 82 may include a protective cover 83, or removable enclosure, that covers the transformer testing system 40 during transport by the vehicle. The protective cover 83 may partially or completely surround the transformer testing system 40. In various embodiments, the protective cover 83 may be a rigid material, a fabric material, or a combination thereof. In some embodiments, the protective cover 83 may include at least one, two, or three movable fabric curtains 85 connected to an otherwise rigid enclosure. The entire protective cover 83 may be removed during testing by the transformer testing system 40. Alternatively, a removable top panel 87 and/or the fabric curtains 85 may be removed during testing. The protective cover 83 may be made from a moisture resistant material (e.g., polyvinyl chloride, polyester, fluoropolymers, sulfonated polymers, polyamides, polyimides, cellulosic polymers, expanded polytetrafluoroethylene (ePTFE), or a combination thereof).

The mobile platform 82 may include a front side 84 and a back side 86. The front side 84 may be coupled to a motorized vehicle during transport of the transformer testing system 40. The mobile platform 82 may include one or more adjustable support legs 88, which may be used to support the mobile platform 82 when not coupled to the vehicle and/or during testing of the transformer 10. In addition, the mobile platform 82 may include one or more sets of wheels 90 to enable movement of the mobile platform 82. A control room 92 may be disposed near the front end 84 of the mobile platform 82. The control room 92 may be used to provide an enclosure for personnel during the impulse testing and may include various components of the transformer testing system 40. Specifically, the control room 92 may include the impulse generator controls 44 and the HIAS 48. As shown in FIG. 3, the control cabinet 54 may be disposed adjacent to the control room 92. The DC hi-pot 46 may be disposed on the mobile platform 82 adjacent a base 94 of the impulse generator tower 56. The impulse generator tower 56 may include one or more support columns 93 to provide a framework for the tower 56. The base 94 of the impulse generator tower 56 may include one or more support legs 96 used to support the impulse generator tower 56 when not in the lowered position 80. The mobile transformer testing system 40 may also include a cushioning system 98 disposed between the mobile platform 82 and the impulse generator tower 56. The cushioning system 98 may be used to cushion or support the impulse generator tower 56 during transport. For example, the cushioning system 98 may include, but is not limited to, foam, rubber, plastic, wood, metal, or a combination thereof. In addition, the mobile transformer testing system 40 may include a tower locking system 100 that locks the impulse generator tower 56 relative to the mobile platform 82 when in the lowered position 80. For example, the tower locking system 100 may be a physical, positive lock that helps lock the impulse generator tower 56 and/or a security lock, such as a keyed lock or combination lock, to prevent unauthorized personnel from moving the impulse generator tower 56. The mobile transformer testing system 40 also includes a drive unit 127 of a tower lift system 123 and a tower bracing system 124, as discussed in detail below.

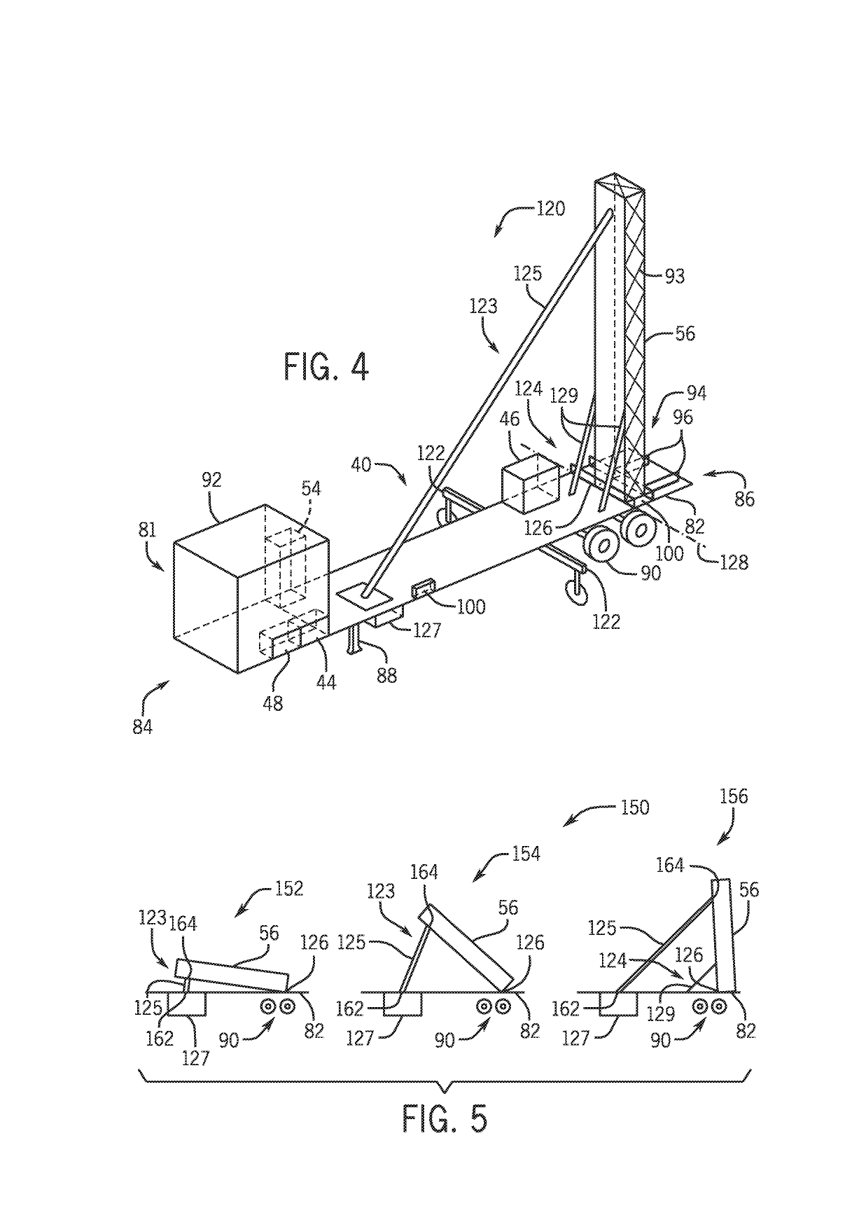

FIG. 4 is perspective view of the mobile transformer testing system 40 in a raised position 120. The mobile platform 82 may include one or more stabilizer systems 122 to stabilize the mobile platform 82 relative to the ground. For example, each stabilizer system 122 may include one or more outriggers, struts, or supports that extend outwardly from the mobile platform 82 to the ground, such as hydraulically driven stabilizers. A tower lift system 123 may be used to lift the impulse generator tower 56 from the lowered position 80 to the raised position 120, as described in detail below with respect to FIG. 5. The tower lift system 123 may include a lift arm 125 and the drive unit 127. The tower bracing system 124 may be used to brace the impulse generator tower 56 in the raised position 120 relative to the mobile platform 82 after using the tower lift system 123. For example, the tower bracing system 124 may include one or more bracing legs 129 coupled to the mobile platform 82 and the impulse generator tower 56. In other embodiments, the tower bracing system 124 may include struts, cables, hydraulically driven arms, or other structural members to help secure the impulse generator tower 56 in the raised position 120. In certain embodiments, the base 94 may be a rotatable base that rotates the impulse generator tower 56 between the lowered position 80 and the raised position 120. In other words, a pivot 126, or rotatable joint, of the base 94 may rotate about an axis 128. In further embodiments, the mobile platform 82 may include the tower locking system 100 that locks the impulse generator tower 56 relative to the mobile platform 82 when in the raised position 120. Once the impulse generator tower 56 is in the raised position 120, testing of the transformer may be performed, as described in detail below.

FIG. 5 is a side view of stages 150 in lifting the impulse generator tower 56. For example, in a first stage 152, the impulse generator tower 56 is in the lowered position 80. In a second stage 154, the impulse generator tower 56 is approximately half way between the lowered position 80 and the raised position 120. In a third stage 156, the impulse generator tower 56 is essentially in the raised position 120. The drive unit 127 may be used to lift the impulse generator tower 56 from the first stage 152 to the third stage 156. In certain embodiments, the drive unit 127 may be disposed under the mobile platform 82. The lift system 127 may be a hydraulically-driven lift, a motorized lift, a cable and pulley lift, or any combination thereof. For example, a hydraulic lift system 123 may include the hydraulic lift arm 125 coupled to the drive unit 127 at a first connection 162 and coupled to the impulse generator tower 156 at a second connection 164. The first and second connections 162 and 164 may include rotational joints (or pivot points) to enable the hydraulic arm 125 to pivot with respect to the mobile platform 82 and/or the impulse generator tower 56. In addition, the impulse generator tower 56 may be configured to rotate or pivot about the rotational joint or pivot joint 126. As shown in the second stage 154, the hydraulic arm 125 has extended partially to raise the impulse generator tower 56 to approximately half way to the raised position 120. In the third stage 156, the hydraulic arm 125 has fully extended to bring the impulse generator tower 56 to the raised position 120. The hydraulic arm 125 may be used as the tower bracing system 124 or separate bracing legs 129 may be coupled to the mobile platform 82 and the impulse generator tower 156 in the third stage 156. For example, the hydraulic arm 125 may be lowered or withdrawn to avoid interfering with electrical connections, and the bracing legs 129 used to support the impulse generator tower 156 in the upright position. In other embodiments, other methods, such as mechanical systems, gear systems, cable and pulley systems, electrical motors, internal combustion engines, and so forth, may be used instead of the hydraulic system for the lift system 123. In addition, the lift system 123 may be powered by the vehicle or include its own power source.

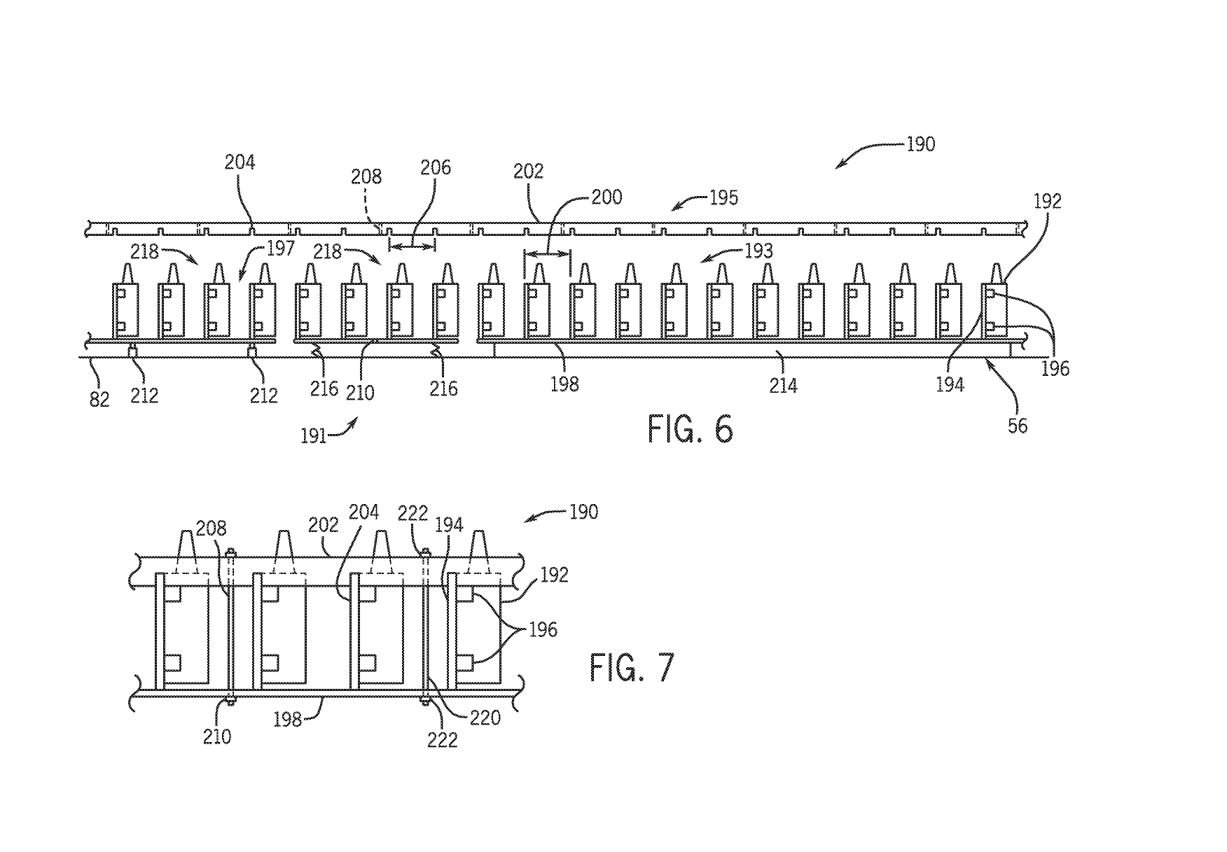

FIG. 6 is a side view of a transport stabilizing system 190 for the impulse generator tower 56. Specifically, the transport stabilizing system 190 includes a cushioning system 191 may be used to cushion, dampen vibrations, or generally stabilize the impulse generator tower 56 while in the lowered position 80 during transport, as described in detail below. As shown in FIG. 6, the impulse generator tower 56 includes a plurality of capacitors 192, which together constitute the impulse generator 193 of the impulse generator tower 56. The capacitors 192 may be separated by spark gaps 197. Each of the capacitors 192 is coupled to a shelf 194 via one or more connectors 196. Each of the shelves 194 may be coupled to a back panel 198 to support all of the capacitors 192 of the impulse generator tower 56. As shown in FIG. 6, the shelves 194 are separated by a distance 200. The transport stabilizing system 190 also includes a bracing system 195. A removable brace 202, which is part of the bracing system 195, is shown in FIG. 6 above the impulse generator tower 56 prior to coupling with the impulse generator tower 56. In certain embodiments, the bracing system 195 may be made from wood or other materials, such as metal or plastic, and may be a single piece or from several pieces coupled together. The brace 202 may include a plurality of notches 204 configured to engage with the shelves 194. For example, the notches 204 may be separated by a distance 206, which corresponds with the distance 200 between the shelves 194. In addition, the brace 202 may include a plurality of brace holes 208 generally aligned with a plurality of panel holes 210 formed in the back panel 198. As discussed in detail below, the holes 208 and 210 may be used to couple the brace 202 to the impulse generator tower 56.

In other embodiments, the cushioning system 191 may include a shock absorber, a vibration damping material, or similar device/material placed between the impulse generator tower 56 and the mobile platform 82. For example, one or more shock absorbers 212 may be placed between the back panel 198 and the mobile platform 82. In other embodiments, the back panel 198 may be placed on a bed of a cushioning material 214, such as foam, rubber, and so forth. In further embodiments, springs 216 may be placed between the back panel 198 and the mobile platform 82. In addition, the impulse generator tower 56 may include a plurality of tower segments 218 selectively disconnected from one another in the lowered position 80 and selectively connected together prior to lifting by the lift system 123. The impulse generator tower 56 may be less susceptible to shock and stress during transport when separated into the tower segments 218, cushioned by the cushioning system 191, and braced by the bracing system 195.

FIG. 7 is a side view of the brace 202 coupled to the impulse generator tower 56 for transport. As shown in FIG. 7, a plurality of support rods 220 may be inserted through the holes 208 and 210. For example, both ends of the support rod 220 may be threaded to engage with nuts 222 to secure the brace 202 to the impulse generator tower 56. The support rods 220 may be made from a non-conductive material, such as a glass woven fabric impregnated with an epoxy resin binder. In other embodiments, the support rods 220 may be made from an elastic material, such as rubber, straps, fabric, rope, and so forth, to provide some resiliency between the brace 202 and the impulse generator tower 56. Coupling the impulse generator tower 56 to the brace 202 may help block movement of the impulse generator tower 56 during transport, thereby helping to prevent damage to the impulse generator tower 56.

The mobile transformer testing system 40 described above enables testing of the transformer 10 to be performed in-situ, or at the facility where the transformer 10 is used. Thus, the cost, downtime, and complexity associated with transporting the transformer 10 to the repair shop may be avoided. The mobile transformer testing system 40 may include various features to facilitate transport of the impulse generator tower 56 and associated equipment. Such features may help to protect the mobile transformer testing system 40 during transport. For example, the mobile transformer testing system 40 may be protected from weather and other risks associated with transport by the protective cover 83. In addition, the transport stabilizing system 190 may be used to cushion and brace the impulse generator tower 56 during transport. Once the mobile transformer testing system 40 arrives at the facility with the transformer 10, the protective cover 83 and transport stabilizing system 190 may be removed to enable setup of the system 40 for testing of the transformer 10. For example, the tower lift system 123 may be used to raise the impulse generator tower 56 to the raised position 120. Afterwards, the tower bracing system 124 may be used to brace the impulse generator tower 56 in the raised position 120. Thus, the impulse generator tower 56 may be safely used to perform testing of the transformer 10. Once testing of the transformer 10 is complete, the tower bracing system 124 may be removed and the tower lift system 123 used to lower the impulse generator tower 56 to the lowered position 80. The transport stabilizing system 190 and the protective cover 83 may be reinstalled to enable the mobile transformer testing system 40 to be moved to the next facility for testing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A system, comprising:
a transformer testing system, comprising:
a mobile platform configured to couple to a vehicle;
an impulse testing system coupled to the mobile platform, wherein the impulse testing system comprises an impulse generator tower disposed in a lowered position along the mobile platform during transport by the vehicle;
a lift system coupled to the mobile platform, wherein the lift system is configured to lift the impulse generator tower from the lowered position to a raised position, wherein the impulse testing system is configured to perform an impulse test of a high voltage power transformer while the impulse generator tower is disposed in the raised position; and
a protective cover disposed on the mobile platform, wherein the protective cover is configured to surround a region having the impulse testing system.

2. The system of claim 1, wherein the vehicle comprises a trailer or a motorized vehicle having the mobile platform.

3. The system of claim 1, wherein the impulse testing system comprises:
an impulse generator disposed in the impulse generator tower, wherein the impulse generator has a cumulative charging voltage greater than approximately 2000 kilovolts;
a charging unit configured to charge the impulse generator;
a control unit configured to provide power to the charging unit;
an impulse voltage divider configured to convert impulse voltages generated by the impulse generator to a lower voltage level;
a controller configured to operate the impulse testing system;
an operator interface configured to enable an operator to interact with the controller; and
an impulse analyzing system configured to analyze results of an impulse test.

4. The system of claim 1, wherein the impulse generator tower comprises:
a plurality of support columns comprising a non-conductive material;
a plurality of capacitors coupled to the plurality of support columns, wherein each of the plurality of capacitors is rated for greater than approximately 2 microfarads and the plurality of capacitors are connected in series via spark gaps; and
a support base coupled to the plurality of support columns.

5. The system of claim 1, wherein the impulse generator tower comprises a rotatable base coupled to the mobile platform, and the rotatable base is configured to rotate the impulse generator tower between the lowered position and the raised position.

6. The system of claim 1, comprising a tower locking system configured to lock the impulse generator tower relative to the mobile platform in the lowered position and the raised position.

7. The system of claim 1, comprising a tower bracing system configured to brace the impulse generator tower relative to the mobile platform in the raised position.

8. The system of claim 1, comprising a stabilizer system configured to stabilize the mobile platform relative to the ground.

9. The system of claim 1, comprising a cushioning system configured to cushion the impulse generator tower in the lowered position during transport by the vehicle.

10. The system of claim 1, wherein the lift system comprises a hydraulically driven lift.

11. The system of claim 1, wherein the protective cover comprises a removable enclosure configured to selectively cover the impulse testing system during transport by the vehicle, and the removable enclosure is configured to selectively uncover the impulse testing system during the impulse test.

12. The system of claim 1, wherein the protective cover comprises a removable wall or curtain made of a fabric material.

13. The system of claim 1, comprising a tower bracing system configured to brace the impulse generator tower relative to the mobile platform in the lowered position.

14. A system, comprising:
a transformer testing system, comprising:
a mobile platform configured to couple to a vehicle;
an impulse testing system comprising an impulse generator tower having a rotatable base coupled to the mobile platform;
a lift system coupled to the mobile platform, wherein the lift system is configured to move the impulse generator tower between a lowered transport position and a raised testing position; and
a cushioning system configured to cushion the impulse generator tower relative to the mobile platform in the lowered position during transport by the vehicle.

15. The system of claim 14, wherein the cushioning system comprises a shock absorber, a vibration damping material, or a combination thereof, between the impulse generator tower and the mobile platform.

16. The system of claim 14, wherein the impulse generator tower comprises a plurality of tower segments selectively disconnected from one another in the lowered transport position during transport by the vehicle, and the plurality of tower segments are selectively connected together prior to lifting by the lift system.

17. The system of claim 14, wherein the impulse generator tower comprises:
a plurality of support columns comprising a non-conductive material;
a plurality of capacitors coupled to the plurality of support columns, wherein each of the plurality of capacitors is rated for greater than approximately 2 microfarads and the plurality of capacitors are connected in series via spark gaps; and
a support base coupled to the plurality of support columns.

18. A system, comprising:
a transformer testing system, comprising:
a mobile platform configured to couple to a vehicle;
an impulse testing system comprising an impulse generator tower having a rotatable base coupled to the mobile platform, wherein the impulse generator tower comprises a plurality of tower segments configured to selectively connect and disconnect from one another; and
a lift system coupled to the mobile platform, wherein the lift system is configured to move the impulse generator tower between a lowered transport position and a raised testing position, wherein the plurality of tower segments are selectively disconnected from one another in the lowered transport position during transport by the vehicle, and the plurality of tower segments are selectively connected together prior to lifting by the lift system.

19. The system of claim 18, comprising a removable fabric cover configured to selectively surround a region having the impulse testing system, wherein the removable fabric cover comprises a fabric curtain or a fabric wall.

20. The system of claim 18, comprising a tower bracing system configured to brace the impulse generator tower relative to the mobile platform in the lowered position or the raised position.
